(19) United States
(12) Patent Application Publication
(10) Pub. No.: US 2009/0127557 A1
(43) Pub. Date: May 21, 2009

(54) METHOD FOR FORMING A POLYSILICON THIN FILM LAYER

(75) Inventors: Tsung-Yen LIN, ChuNan (TW); Ho-Hsuan Lin, ChuNan (TW); Wen-Tseng Cheng, ChuNan (TW); Shan-Hung Tsai, ChuNan (TW)

Correspondence Address: VENABLE LLP, P.O. BOX 34385, WASHINGTON, DC, 20043-9998, US

(73) Assignee: TPO Displays Corp., Chu-Nan (TW)

(21) Appl. No.: 12/268,779

(22) Filed: Nov. 11, 2008

(30) Foreign Application Priority Data
Nov. 16, 2007 (TW) 96143562

(51) Int. Cl. H01L 21/8238; H01L 29/04

(52) U.S. Cl. 257/59; 438/289; 257/E21.632; 257/E29.003

(57) ABSTRACT

This invention provides a method for fabricating a polysilicon thin film layer, which performs a gas plasma treatment on channel regions defined in the polysilicon thin film layer after the polysilicon thin film layer is formed on a substrate. Threshold voltages for polysilicon thin film transistors formed subsequently are thus adjusted by the gas plasma treatment. A gate insulating layer is formed on the polysilicon thin film layer after the gas plasma treatment.

### BACKGROUND OF THE INVENTION

1. Field of the Invention

The present invention relates to a method for fabricating a polysilicon thin film layer, and more particularly to a method of surface treatment for a polysilicon thin film layer.

2. Description of the Related Art

Conventional methods for fabricating low-temperature polysilicon thin film transistors (LTPS TFTs) typically include the following steps. First, a thin amorphous silicon layer is formed on an insulating substrate, such as a glass substrate or a quartz substrate. Then, an excimer laser annealing (ELA) process is performed for the thin amorphous silicon layer so that it can be re-crystallized to form a thin polysilicon layer. A plurality of source/drain regions and channel regions are defined in the thin polysilicon layer, which will be the active layer of the subsequently formed polysilicon thin film transistor. A gate oxide layer is then formed on the thin polysilicon layer. Since in the conventional LTPS TFT fabrication processes, it is difficult to control the quality in channel regions of the thin polysilicon layer, threshold voltages for the polysilicon thin film transistors subsequently formed tend to fluctuate, which may prohibit the polysilicon thin film transistors from proper functions. Thus, in the conventional LTPS TFT fabrication processes, ion implantation is generally performed for channel regions after source/drain regions and channel regions in the thin polysilicon layer are defined. Through adjusting the dose of implanted ions, threshold voltage values for the polysilicon thin film transistors formed subsequently can be adjusted accordingly.

FIG. 1A is a chart showing the threshold voltages (Vₜₕ) of a conventional N-channel thin film transistor with dosage of ions implanted into channel regions. In this chart, the y-axis shows the threshold voltage and the x-axis shows the test position number of wafer, wherein the ion implantation is performed at an energy of 10 Kev and a dosage of 6×10¹¹ to 2×10¹² ions/cm³. FIG. 1B is a chart showing the threshold voltages (Vₜₕ) of a conventional P-channel thin film transistor with dosage of ions implanted into channel regions. In this graph, the y-axis shows the threshold voltage and the x-axis shows the test position number of wafer, wherein the ion implantation is performed at an energy of 15 Kev and a dose of 6×10¹¹ to 2×10¹² ions/cm³.

However, threshold voltage values for polysilicon thin film transistors are not easily controllable performing conventional ion implantation techniques for channel regions; besides, the cost and time spent for fabricating polysilicon thin film transistors are both considerable. It is therefore desirable to provide a method for fabricating a thin polysilicon layer that overcomes the drawbacks of the conventional methods.

### SUMMARY OF THE INVENTION

The present invention provides a method for fabricating a polysilicon thin film layer, which performs a gas plasma treatment for channel regions defined in a polysilicon thin film layer before a gate insulating layer is formed thereon. Threshold voltages required for polysilicon thin film transistors subsequently formed are thus adjusted by the gas plasma treatment, and facilitating the polysilicon thin film transistors function properly.

The method for fabricating a polysilicon thin film layer of the present invention includes forming a polysilicon film on a substrate, defining a plurality of source/drain regions and a plurality of channel regions in the polysilicon film, and performing a gas plasma treatment for the channel regions of the polysilicon film.

The present invention replaces an ion implantation performed for channel regions in the conventional manufacturing process with the gas plasma treatment so that the threshold voltages for polysilicon thin film transistors formed subsequently can be adjusted. By using the method for fabricating a polysilicon thin film layer of the present invention, the step of performing ion implantation for channel regions could be omitted, and both time and cost for the entire fabrication process could be further reduced.

### BRIEF DESCRIPTION OF THE DRAWINGS

FIG. 1A is a chart showing the threshold voltages (Vₜₕ) of a conventional N-channel thin film transistor with dosage of ions implanted into channel regions;

FIG. 1B is a chart showing the threshold voltages (Vₜₕ) of a conventional P-channel thin film transistor with dosage of ions implanted into channel regions;

FIGS. 2A through 2C are cross-sectional views respectively corresponding to various stages of fabricating a thin film transistor having a polysilicon active layer of the present invention;

FIG. 3A is a chart showing the threshold voltages (Vₜₕ) of an N-channel thin film transistor according to the present invention with pressures of N₂O gas plasma;

FIG. 3B is a chart showing the threshold voltages (Vₜₕ) of a P-channel thin film transistor according to the present invention with pressures of N₂O gas plasma;

FIG. 4A is a chart showing the threshold voltages (Vₜₕ) of an N-channel thin film transistor according to the present invention with the power levels of N₂O gas plasma;

FIG. 4B is a chart showing the threshold voltages (Vₜₕ) of a P-channel thin film transistor according to the present invention with power levels of N₂O gas plasma;

FIG. 5A is a chart showing the threshold voltages (Vₜₕ) of an N-channel thin film transistor according to the present invention with treatment time of N₂O gas plasma treatment;

FIG. 5B is a chart showing the threshold voltages (Vₜₕ) of a P-channel thin film transistor according to the present invention with treatment time of N₂O gas plasma treatment;

FIG. 6 is a chart showing the threshold voltages (Vₜₕ) of an N-channel and P-channel thin film transistors according to the present invention with pressures of H₂ gas plasma; and

FIG. 7 is a chart showing the threshold voltages (Vₜₕ) of an N-channel and P-channel thin film transistors according to the present invention with the pressures of NH₃ and H₂ gas plasmas.

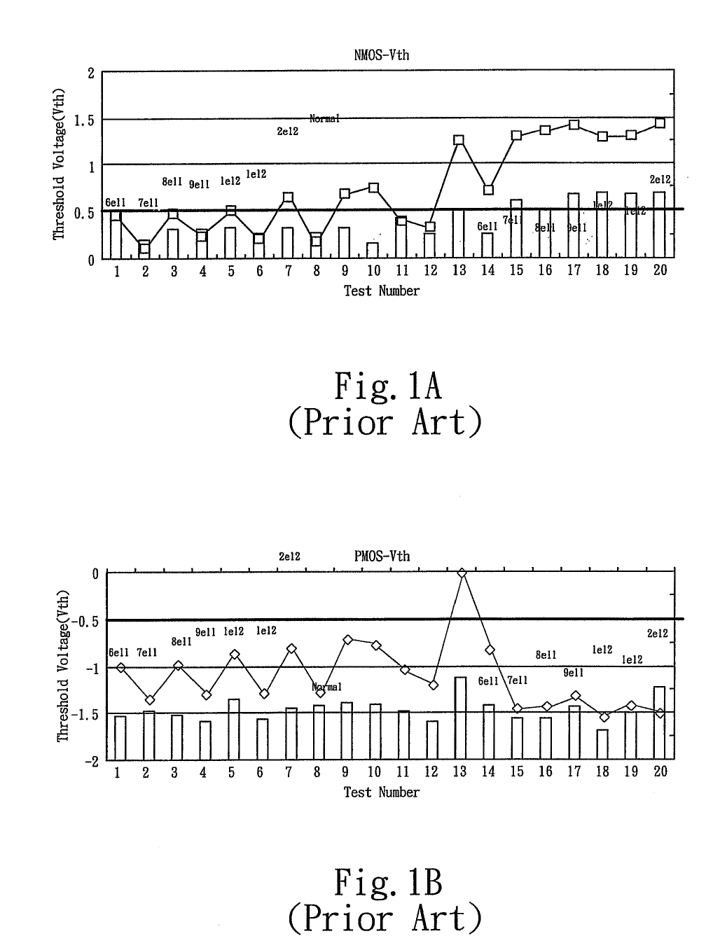

### DETAILED DESCRIPTION OF THE PREFERRED EMBODIMENTS

The method for fabricating a polysilicon thin film layer of the present invention is further described as follows with embodiments and accompanying drawings.

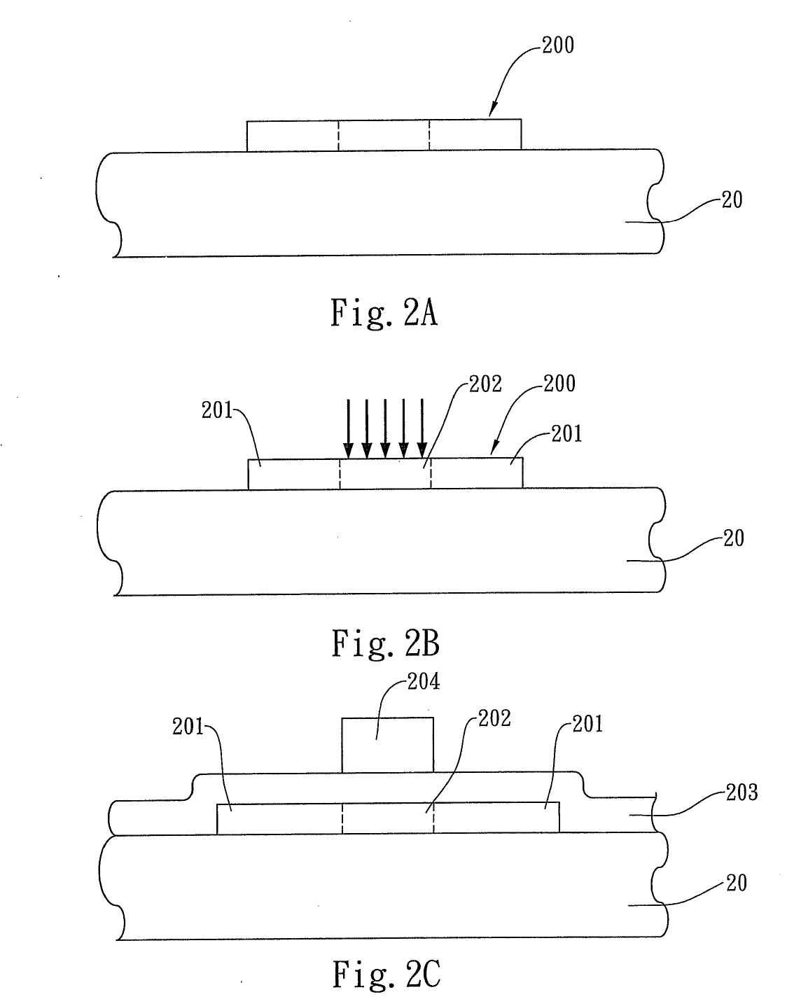

FIGS. 2A through 2C are cross-sectional views corresponding to various stages of fabricating a thin film transistor having a polysilicon active layer of the present invention. Referring to FIG. 2A, an amorphous silicon layer is firstly formed on an insulating substrate 20 by sputtering or deposition. The insulating substrate 20 can be a glass substrate or a quartz substrate. Next, an excimer laser annealing process (ELA) is performed for the amorphous silicon layer so that the amorphous silicon layer is re-crystallized to become a polysilicon film 200. The polysilicon film 200 is served as an active layer of a polysilicon thin film transistor formed subsequently. Then, a plurality of source/drain regions 201 and channel regions 202 are defined in the polysilicon film 200. Referring to FIG. 2B, a gas plasma treatment is performed on the channel region 202 of the polysilicon film 200 for a predetermined time. The gas plasma used in this invention can be N₂O, H₂ or NH₃ gas plasma, and the control variable in the gas plasma treatment can be the pressure of the gas plasma, power level of the gas plasma, or treatment time of the gas plasma. After the gas plasma treatment is done to the channel region 202 of the polysilicon film 200, an insulating layer 203 is formed over the polysilicon film 200. The insulating layer 203 serves to be a gate oxide layer for a thin film transistor formed subsequently. Then, a gate electrode 204 corresponding to the channel region 202 is formed on the insulating layer 203, and the fabrication of a polysilicon thin film transistor is thus completed.

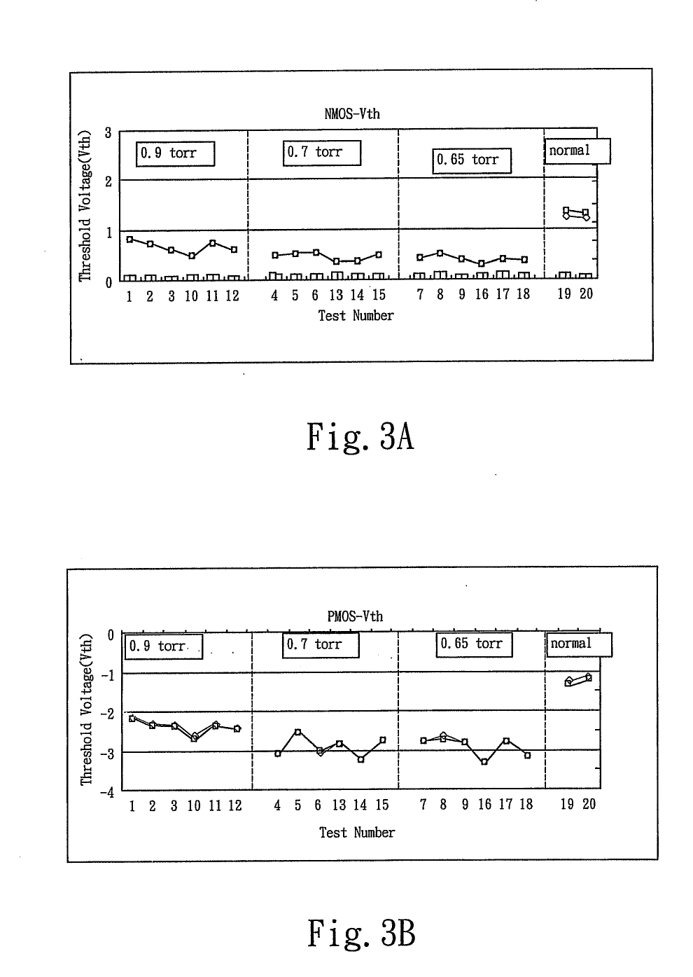

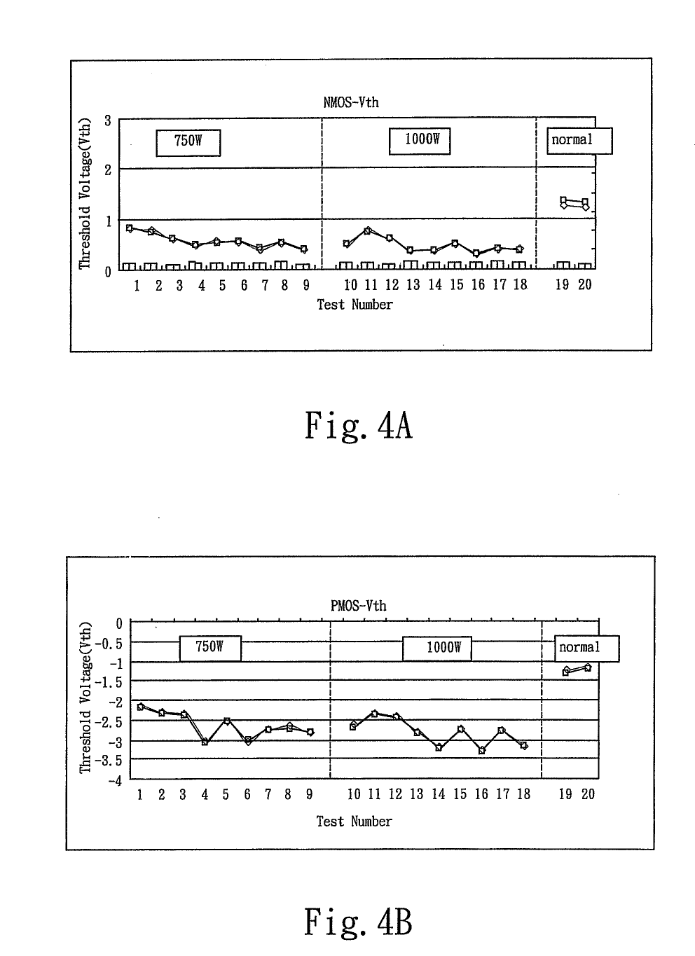

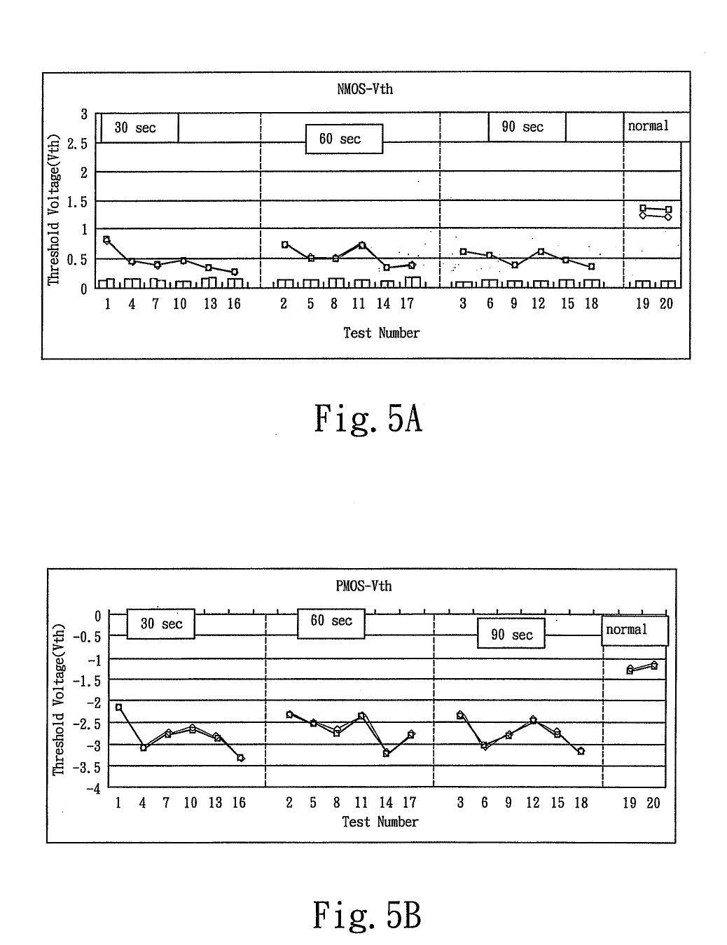

Referring to FIG. 2B, N₂O is the source gas applied in gas plasma treatment, wherein the control variable is the pressure of N₂O gas plasma, e.g. 0.65 to 0.9 torr in this embodiment. It is clear that when the pressure of N₂O gas plasma is increased, the threshold voltage (Vₜₕ) of the subsequently formed N-channel polysilicon thin film transistor and P-channel polysilicon thin film transistor also increases respectively, as shown in FIG. 3A and FIG. 3B. Next, the control variable is changed to the power level of N₂O gas plasma, e.g. 750 to 1000 W in this embodiment. It is clear that when the power level of N₂O gas plasma is reduced, the threshold voltage (Vₜₕ) of the subsequently formed N-channel polysilicon thin film transistor and P-channel polysilicon thin film transistor, in contrast, increases respectively, as shown in FIG. 4A and FIG. 4B. Then, the control variable is changed to the treatment time of N₂O gas plasma treatment, e.g. 30 to 90 seconds in this embodiment. It is clear that when the treatment time of N₂O gas plasma is longer, the threshold voltage (Vₜₕ) of the subsequently formed N-channel polysilicon thin film transistor and P-channel polysilicon thin film transistor increases respectively, as shown in FIG. 5A and FIG. 5B.

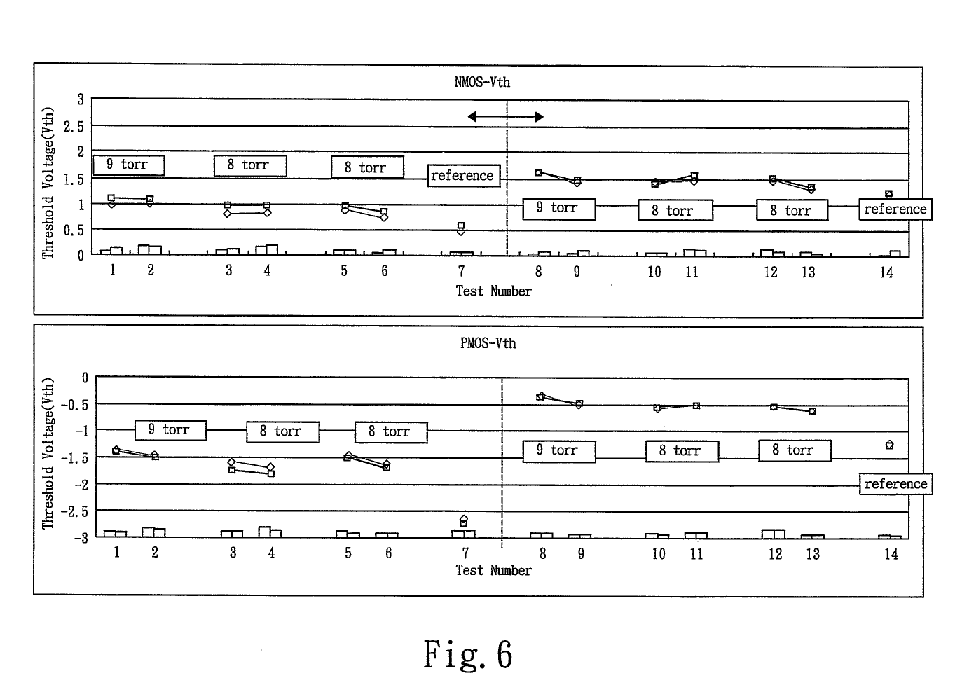

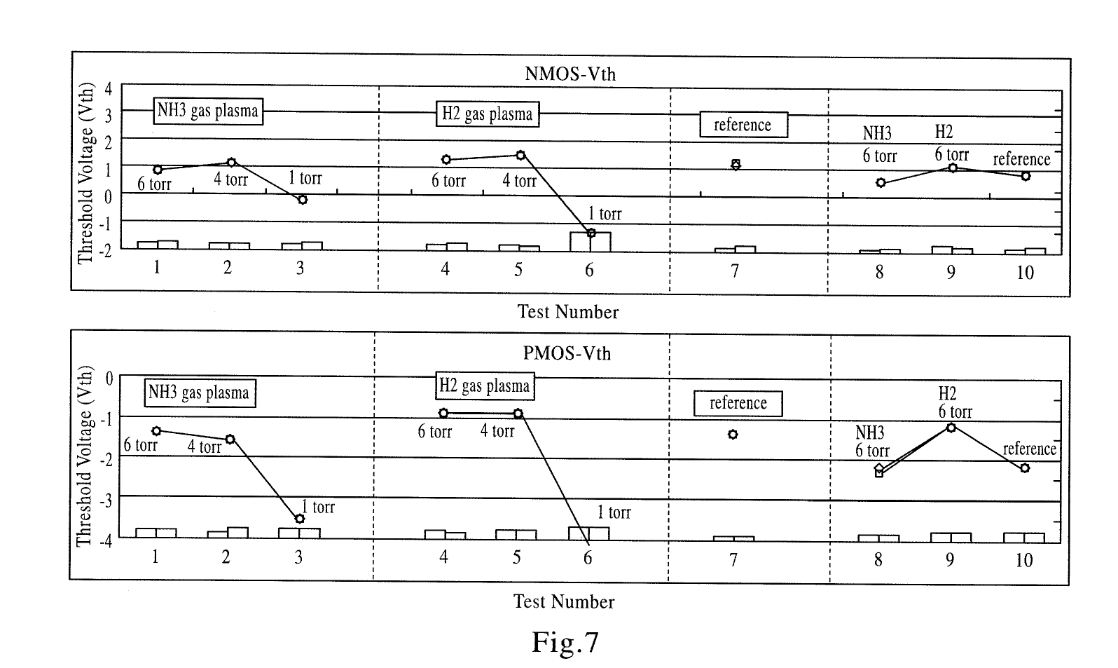

In another embodiment, H₂ is applied as the source gas and the pressure of H₂ gas plasma is set as the control variable in the gas plasma treatment, wherein H₂ gas plasma is at a pressure between 1 and 9 torr, at a constant value of power level between 700 and 2000 W, and at a constant value of treatment time between 30 and 90 seconds. It is clear that when the pressure of H₂ gas plasma is increased, the threshold voltage (Vₜₕ) of the subsequently formed N-channel polysilicon thin film transistor and P-channel polysilicon thin film transistor also increases respectively, as shown in FIG. 6 and FIG. 7.

In yet another embodiment, NH₃ is applied as the source gas and the pressure of NH₃ gas plasma is set as the control variable in the gas plasma treatment, wherein NH₃ gas plasma is at a pressure between 1 and 6 torr, at a power level of 800 W, and at a constant value of treatment time between 30 and 90 seconds. It is clear that when the pressure of NH₃ gas plasma is increased, the threshold voltage (Vₜₕ) of the subsequently formed N-channel polysilicon thin film transistor and P-channel polysilicon thin film transistor also increases respectively, as shown in FIG. 7.

In the present invention, a gas plasma treatment is performed for the channel regions of the polysilicon film 200. After the gas plasma treatment, the threshold voltage (Vₜₕ) of the N-channel metal-oxide-semiconductor field-effect transistor (MOSFET) formed subsequently ranges from 0 to 3 volts, and the threshold voltage (Vₜₕ) of the P-channel MOSFET ranges from −3 to 0 volts. The gas plasma treatment according to the present invention is performed for the channel regions of the polysilicon film 200 before a gate insulating layer is formed. Consequently, the threshold voltage (Vₜₕ) for the polysilicon thin film transistor formed subsequently can be adjusted, which enables the polysilicon thin film transistor to function properly.

The method for fabricating a polysilicon thin film layer of the present invention could be applied to fabricating polysilicon thin film transistors. With such application, the channel doping process in the conventional manufacturing method for fabricating polysilicon thin film transistors could be omitted, and as a result, both cost and time for fabrication could be reduced. Moreover, a polysilicon thin film transistor made from a polysilicon film 200 according to the present invention could be applied to productions of an image display system, wherein the image display system includes a display device which may be an LCD device or an OLED device. The image display system could be included in an electronic device, wherein the electronic device has an input unit coupled to the image display device; signals are sent by the input unit to the image display device to control its display of images. The electronic device can be a personal digital assistant (PDA), cellular phone, digital camera, television, Global positioning system (GPS) receiver, automotive display, aircraft display, digital photo frame, notebook computer, desktop computer, or portable DVD player.

Besides, the present invention could be carried out with an alternative process. After an ELA process is performed for the amorphous silicon layer and the polysilicon film 200 is formed accordingly, ion implantation is performed for the channel region of the polysilicon film 200 to adjust the threshold voltage for the polysilicon thin film transistor formed subsequently. Then, a gas plasma treatment is performed for the channel region of the polysilicon film 200, and thus, the threshold voltage for the polysilicon thin film transistor formed subsequently can be further fine-adjusted.

While this invention has been described by way of examples and in terms of preferred embodiments, it is to be understood that this invention is not limited hereto, and that various changes, substitutions, and alterations can be made herein without departing from the spirit and scope of this invention as defined by the appended claims.

What is claimed is:

1. A method for fabricating a polysilicon thin film layer, comprising:
forming a polysilicon film on a substrate, wherein a plurality of source/drain regions and a plurality of channel regions are defined in the polysilicon film; and
performing a gas plasma treatment for the channel regions of the polysilicon film.

2. The method of claim 1, wherein the gas plasma treatment is performed with gas plasmas including N₂O, H₂ or NH₃.

3. The method of claim 1, wherein an ion implantation is performed for the channel regions prior to the gas plasma treatment.

4. The method of claim 1, wherein a control variable in the gas plasma treatment is pressure of the gas plasma, power level of the gas plasma, or treatment time of the gas plasma.

5. The method of claim 1, wherein the step of forming the polysilicon film comprising forming an amorphous silicon layer on the substrate and performing a laser annealing process for the amorphous silicon layer.

6. The method of claim 2, wherein the step of forming the polysilicon film comprising forming an amorphous silicon layer on the substrate and performing a laser annealing process for the amorphous silicon layer.

7. The method of claim 2, wherein an ion implantation is performed for the channel regions prior to the gas plasma treatment.

8. The method of claim 2, wherein a control variable in the gas plasma treatment is pressure of the gas plasma, power level of the gas plasma, or treatment time of the gas plasma.

9. The method of claim 8, wherein the pressure of N₂O gas plasma is between 0.65 and 0.9 torr.

10. The method of claim 8, wherein the pressure of H₂ gas plasma is between 1 and 9 torr.

11. The method of claim 8, wherein the pressure of NH₃ gas plasma is between 1 and 6 torr.

12. The method of claim 8, wherein the power level of N₂O gas plasma is between 750 and 1000 W.

13. The method of claim 8, wherein the power level of H₂ gas plasma is between 700 and 2000 W.

14. The method of claim 8, wherein the power level of NH₃ gas plasma is 800 W.

15. The method of claim 8, wherein the treatment time of the gas plasma is between 30 and 90 seconds.

16. The method of claim 1, wherein an N-channel MOSFET or a P-channel MOSFET is fabricated, wherein:
a threshold voltage (Vₜₕ) of the N-channel MOSFET ranges between 0 to 3 volts; and
a threshold voltage (Vₜₕ) of the P-channel MOSFET ranges between −3 to 0 volts.

17. A method for fabricating an array substrate, comprising:
forming a polysilicon film on a substrate, wherein a plurality of source/drain regions and a plurality of channel regions are defined in the polysilicon film; and
performing a gas plasma treatment for the channel regions of the polysilicon film.

18. The method of claim 17, further comprising forming a gate insulating layer over the channel regions and forming a plurality of gate electrodes, which correspond to respective channel regions, on the gate insulating layer.

19. An electronic device, comprising:
an image display device comprising the array substrate of claim 18; and
an input unit electrically coupled to the image display device, wherein signals are transmitted to the image display device from the input unit to control display of images.

20. The electronic device of claim 19, wherein the electronic device includes a mobile phone, digital camera, personal digital assistant (PDA), notebook computer, desktop computer, television, automotive display, Global positioning system (GPS) receiver, aircraft display, or portable DVD player.
